(19) United States
(12) Patent Application Publication
(10) Pub. No.: US 2025/0096064 A1
(43) Pub. Date: Mar. 20, 2025

(54) WAFER LEVEL CHIP SCALE PACKAGE STRUCTURE AND METHOD OF MANUFACTURING WAFER LEVEL CHIP SCALE PACKAGE

(71) Applicant: ACCELETA CORP., Jeonju-si (KR)

(72) Inventor: Min Suk SUH, Jeonju-si (KR)

(21) Appl. No.: 18/884,645

(22) Filed: Sep. 13, 2024

(30) Foreign Application Priority Data
Sep. 14, 2023 (KR) 10-2023-0122655

(51) Int. Cl. H01L 23/367; H01L 21/48; H01L 21/56; H01L 23/00; H01L 23/31; H01L 25/065

(52) U.S. Cl. CPC H01L 23/3672; H01L 21/4871; H01L 21/565; H01L 23/3128; H01L 23/562; H01L 25/0655

(57) ABSTRACT

The present disclosure provides a wafer level chip scale package structure including a wafer in which a plurality of semiconductor devices are arranged, a heat dissipation plate attached to an upper end of the wafer according to positions of the plurality of semiconductor devices, and a sealing resin placed on an upper portion of the heat dissipation plate to be cured and to seal the wafer and the heat dissipation plate, wherein chip scale packages, each including the wafer, the heat dissipation plate, and the sealing resin bonded to each other according to the semiconductor device, are separated from each other. There are effects in that the heat generated during power semiconductor operation may be effectively dissipate through metal and warpage occurring in a large-area wafer may be prevented.

### CROSS-REFERENCE TO RELATED APPLICATION

This application is based on and claims priority under 35 U.S.C. § 119 to Korean Patent Application No. 10-2023-0122655, filed on Sep. 14, 2023, in the Korean Intellectual Property Office, the disclosure of which is incorporated by reference herein in its entirety.

### BACKGROUND

### 1. Field

The present disclosure relates to a wafer level chip scale package structure and a method of manufacturing a wafer level chip scale package, and more specifically, to a wafer level chip scale package structure that may increase heat dissipation efficiency and prevent warpage of a chip scale package by providing a heat dissipation plate including a metal clip in which heat dissipation holes are formed by laser, on an upper portion of a wafer, and a method of manufacturing a wafer level chip scale package.

### 2. Description of the Related Art

The trend in today's electronics industry is to manufacture lightweight, miniaturized, high-speed, multi-functional, high-performance, and highly reliable products at low cost. One of technologies that make this possible is a semiconductor package technology, and one type of the packages developed recently is a so-called wafer level chip scale package (WLCSP) that uses redistribution or rerouting of bonding pads of a semiconductor chip.

A wafer level package (WLP) technology has been developed in various fields depending on processes and structures, and recently, technologies, such as fan-out WLP (FOWLP) and embedded WLP (eWLP) have been proposed, and in general WLCSP or Fan-in WLP, a package size is the same as a chip size, and thus, the general WLCSP or Fan-in WLP may be applied when the number of inputs/outputs is less, or the chip size is less.

In the Fan-in WLP, reliability problems may occur under environments, such as thermal cycles and thermal shock due to a difference in coefficient of thermal expansion (CTE) between an Si chip and a substrate. In this case, a strain causing thermal stress varies depending on sizes of chips, and the stress that an outermost bonding portion receives increases as the chip size increases.

In addition, recently, wafer level chip scale packages have been manufactured by forming a resin sealing portion in batches at a wafer level and performing a dicing process, but it is necessary to prevent performance of a semiconductor device from being reduced due to heat generation, and there is a problem that, when wafers are made large in size, warping occurs, causing reduction of yield and increase of manufacturing costs.

Accordingly, there is a need for development of a wafer level chip scale package structure and a method of manufacturing a wafer level chip scale package that may prevent warpage in a large-area wafer and effectively dissipate the heat generated during operation.

Examples of related art include Korean Patent No. 10-1569123 Fan-in Type Semiconductor Package Structure and Manufacturing Method (2015, Nov. 9).

### SUMMARY

The present disclosure provides a wafer level chip scale package structure and a method of manufacturing a wafer level chip scale package according to embodiments of the present disclosure that may improve heat dissipation efficiency of a chip scale package while preventing warpage of a processed wafer by bonding a metal clip processed by laser according to a shape of a semiconductor device chip to an upper portion of a wafer and then sealing the metal clip with a resin (an epoxy molding compound (EMC)).

According to an aspect of the present disclosure, a wafer level chip scale package structure includes a wafer in which a plurality of semiconductor devices are arranged, a heat dissipation plate attached to an upper end of the wafer according to positions of the plurality of semiconductor devices, and a sealing resin placed on an upper portion of the heat dissipation plate to be cured and to seal the wafer and the heat dissipation plate, wherein chip scale packages, each including the wafer, the heat dissipation plate, and the sealing resin bonded to each other according to the semiconductor device, are separated from each other.

Here, the heat dissipation plate may include a plurality of heat dissipation holes formed to be equal to a number of the plurality of semiconductor devices and formed to partially expose areas of vertices of the plurality of semiconductor devices, a plurality of clips formed in a cross shape between the plurality of heat dissipation holes according to shapes of the plurality of semiconductor devices and dissipating heat between the plurality of semiconductor devices and the sealing resin, and a warpage prevention portion attached to an upper surface of the wafer in which the plurality of semiconductor devices are not formed.

In addition, the chip scale package may further include an adhesive portion configured to attach the wafer to the heat dissipation plate, and a plurality of shoulder balls formed at a bottom of the wafer and configured to transmit signals generated by the plurality of semiconductor devices to an external device.

In addition, the plurality of clips may be each formed in a cross shape according to the shapes of the plurality of heat dissipation holes, and the clips between the plurality of heat dissipation holes may be processed to be thinner than centers of the plurality of clips such that the centers protrude toward the sealing resin.

In addition, the plurality of chips may respectively include grooves formed in a grid shape in centers of the plurality of clips, and the sealing resin may be injected into the grooves and cured.

According to another aspect of the present disclosure, a method of manufacturing a wafer level chip scale package includes forming a wafer by arranging a plurality of semiconductor devices having the same size in a silicon mold, forming a plurality of heat dissipation holes in a heat dissipation plate according to a number of the plurality of semiconductor devices, manufacturing a plurality of chip scale packages by bonding the wafer to the heat dissipation plate, placing a sealing resin on an upper surface of the heat dissipation plate to which the wafer is bonded, and connecting a plurality of shoulder balls to the wafer, and separating the plurality of chip scale packages from each other according to positions of the plurality of semiconductor devices.

In addition, in the forming of the plurality of heat dissipation holes, the plurality of heat dissipation holes may be formed to be aligned with edges of the plurality of semiconductor devices, and then a plurality of clips may be processed such that the heat dissipation plate partially protrudes in a direction in which the sealing resin is applied.

In addition, in the forming of the plurality of heat dissipation holes, after the plurality of heat dissipation holes are formed to be aligned with edges of the plurality of semiconductor devices, grooves, each having a grid shape, may be formed centers of the plurality of clips of the heat dissipation plate, and in the manufacturing of the plurality of chip scale packages, the sealing resin may be injected into the grooves and cured.

A wafer level chip scale package structure and a method of manufacturing a wafer level chip scale package according to embodiments of the present disclosure may effectively dissipate the heat generated during power semiconductor operation through metal and may prevent warpage occurring in a large-area wafer by safely placing a copper heat dissipation plate on an upper surface of a semiconductor device when manufacturing a semiconductor package.

In addition, the reliability of a wafer-level chip scale package may be improved through a simple process, such as adding a step difference or a groove formed by laser processing to a clip formed according to a shape of a semiconductor device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is an exploded perspective view illustrating a wafer level chip scale package structure according to an embodiment of the present disclosure.

FIG. 2A is a plan view illustrating a wafer illustrated in FIG. 1;

FIG. 2B is a plan view illustrating another example of the wafer illustrated in FIG. 2A;

FIG. 3 is a plan view illustrating a heat dissipation plate illustrated in FIG. 1;

FIG. 4 is a perspective view illustrating components of the wafer level chip scale package structure illustrated in FIG. 1 which are assembled as a chip scale package and separated from each other;

FIG. 5 is a plan view illustrating another shape of the clip illustrated in FIG. 3 and attached to a semiconductor device illustrated in FIG. 1;

FIG. 6 is a cross-sectional view illustrating a state in which the clip illustrated in FIG. 5 is assembled to the chip scale package illustrated in FIG. 4 and cut along a cross-section line A-A;

FIG. 7 is a plan view illustrating a state in which the clip illustrated in FIG. 3 is formed in another shape and attached to a semiconductor device illustrated in FIG. 1;

FIG. 8 is a cross-sectional view illustrating a state in which the clip illustrated in FIG. 7 is assembled to the chip scale package illustrated in FIG. 4 and cut along a cross-section line A-A; and

FIG. 9 is a flowchart illustrating a method of manufacturing a wafer level chip scale package, according to an embodiment of the present disclosure.

### DETAILED DESCRIPTION

Hereinafter, descriptions of the present disclosure made with reference to the drawings are not limited to a specific embodiment, and various transformations may be made, and various embodiments may be made. In addition, the descriptions given below should be understood to include all transformations and replacements included in the idea and technical scope of the present disclosure.

In the following description, the terms, “first”, “second”, and so on, are used to describe various components, and their meanings are not limited in themselves, and are used only for the purpose of distinguishing one component from another component.

The same reference numerals used throughout the present specification represent the same components.

In the present disclosure, the singular expression includes the plural expression unless the context clearly indicates otherwise. In addition, the terms “include”, “comprise”, and “have” described below should be interpreted to specify the presence of features, numbers, steps, operations, constituent elements, components, or combinations thereof described in the specification, and should be understood not to preclude the presence or addition of one or more other features, numbers, steps, operations, constituent elements, components, or combinations thereof.

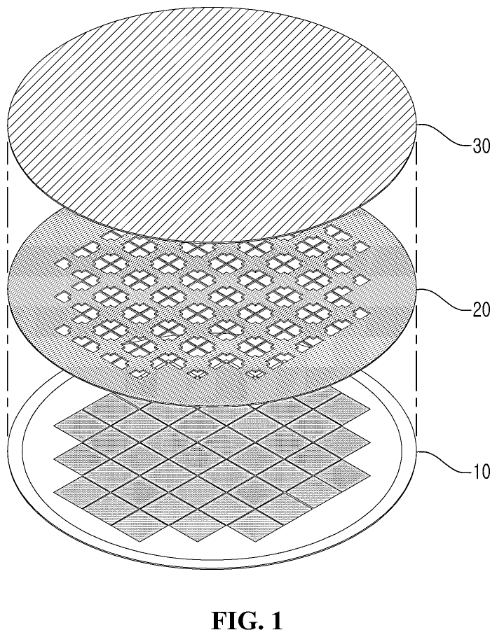

Hereinafter, a wafer level chip scale package structure and a method of manufacturing a wafer level chip scale package, according to embodiments of the present disclosure, will be specifically described with reference to FIGS. 1 to 9.

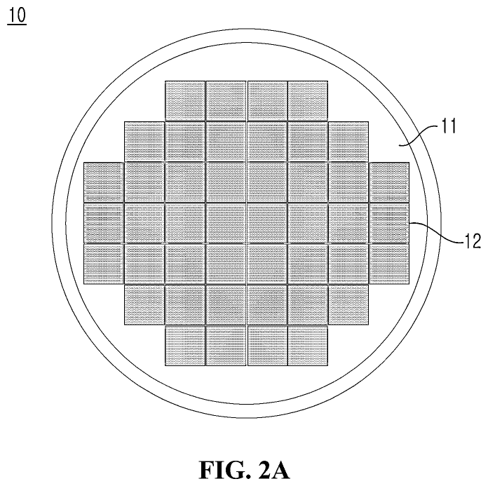

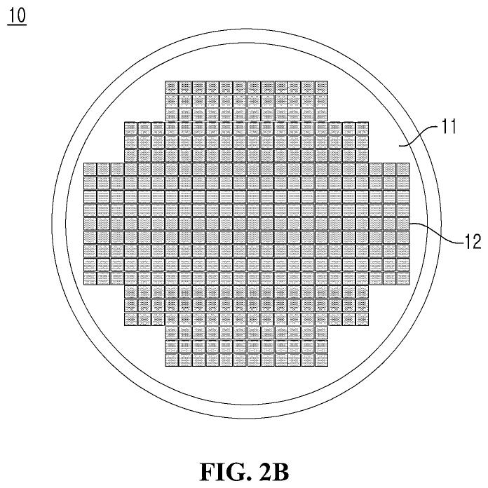

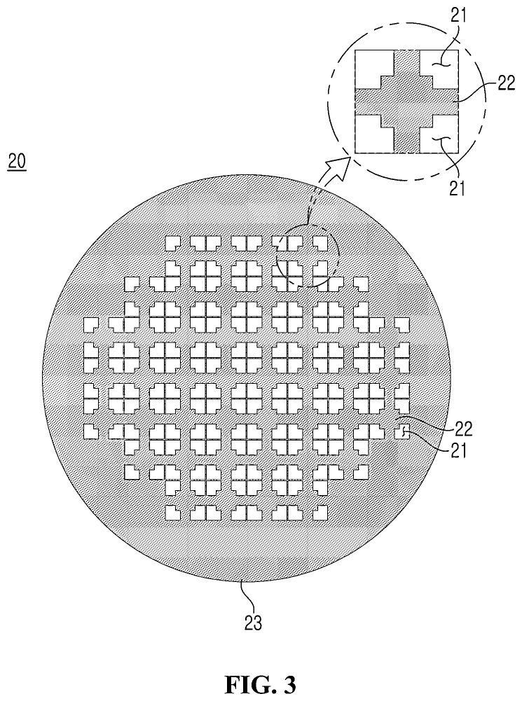

FIG. 1 is an exploded perspective view illustrating a wafer level chip scale package structure according to an embodiment of the present disclosure, FIG. 2A is a plan view illustrating a wafer illustrated in FIG. 1, FIG. 2B is a plan view illustrating another example of the wafer illustrated in FIG. 2A, FIG. 3 is a plan view illustrating a heat dissipation plate illustrated in FIG. 1, and FIG. 4 is a perspective view illustrating components of the wafer level chip scale package structure illustrated in FIG. 1 which are assembled as a chip scale package and separated from each other.

The wafer level chip scale package structure according to the embodiment of the present disclosure may include a wafer 10, a heat dissipation plate 20, and a sealing resin 30.

The wafer 10 may have a plurality of semiconductor devices 12 arranged in the wafer 10.

Specifically, in the wafer 10, the plurality of semiconductor devices 12 may be arranged in rows and columns in a silicon mold 11 in which a plurality of insertion grooves for the plurality of semiconductor devices 12 to be inserted are formed.

Here, the silicon mold 11 may be formed in a circular shape as illustrated in FIG. 2A, and a fixture may be provided along an outer circumferential surface to fix the circular shape of the silicon mold 11.

There may be predetermined intervals between the plurality of semiconductor devices 12 such that the plurality of semiconductor devices 12 may be cut according to sizes thereof after the silicon mold 11 is bonded to the heat dissipation plate 20 and the sealing resin 30 described below.

In this case, the predetermined intervals may be provided as widths that do not damage the plurality of semiconductor devices 12 when the wafer 10 is cut by a laser cutter or a rotary blade cutter.

In addition, small-sized semiconductor devices may be densely arranged in the wafer 10 as illustrated in FIG. 2B, and in this case, the silicon mold 11 may be reduced more than the silicon mold 11 illustrated in FIG. 2A because an area occupied by the plurality of semiconductor devices 12 increases.

In the present specification, for the sake of ease of description, a wafer level chip scale package structure using the wafer 10 illustrated in FIG. 2A will be described as an example.

Referring to FIG. 3, the heat dissipation plate 20 may be attached onto an upper portion of the wafer 10. In this case, the heat dissipation plate 20 may be attached to the wafer 10 such that a plurality of heat dissipation holes 21 are aligned with the plurality of semiconductor devices 12.

Specifically, the heat dissipation plate 20 is formed of a metal material, such as copper, and accordingly, when heat is generated from the plurality of semiconductor devices 12 after a chip scale package is manufactured, the heat may be dissipated more efficiently.

The heat dissipation plate 20 may have the plurality of heat dissipation holes 21 formed according to the number and positions of the plurality of semiconductor devices 12, and as the plurality of heat dissipation holes 21 are formed, clip portions 22 and a warpage prevention portion 23 may be formed.

The plurality of heat dissipation holes 21 may each expose a part of an area of a vertex of each of the plurality of semiconductor devices 12.

The plurality of heat dissipation holes 21 may each be formed in a wide “¬” shape according to a position where each of the plurality of semiconductor devices 12 is formed by laser processing, that is, a corner position of an insertion groove formed in the silicon mold 11. The plurality of heat dissipation holes 21 are preferably formed by laser processing as described above, but are not limited thereto.

In addition, the plurality of heat dissipation holes 21 may cover the intervals between the plurality of semiconductor devices 12 described above, and when the heat dissipation holes 21 are formed near the center of the heat dissipation plate 20, the heat dissipation holes 21 formed on all sides in the shape of a letter “L” may also be formed in an octagonal shape.

Here, the octagonal shape refers to a shape having 12 vertices in which corners except for horizontal and vertical corners of a regular octagonal shape are recessed.

For example, the clip portions 22 may be formed in a cross shape by removing the plurality of heat dissipation holes 21 of an octagonal shape from the heat dissipation plate 20.

The clip portions 22, each having the above-described shape, may dissipate heat between the plurality of semiconductor devices 12 and the sealing resin 30 in a chip scale package. The description of the clip portions 22 in the chip scale package will be described in more detail below.

The warpage prevention portion 23 may be in contact with an outer circumferential surface of the wafer 10 and be formed on an outer side of the plurality of semiconductor devices 12, that is, on an outer side of a portion where the plurality of heat dissipation holes 21 and the clip portions 22 are formed.

The warpage prevention portion 23 may be bonded to a portion of the wafer 10 in which the plurality of semiconductor devices 12 are not formed, thereby preventing the risk of warping when a chip scale package coated up to the sealing resin 30 is separated according to the number of plurality of semiconductor devices 12.

The sealing resin 30 may be injected into an upper portion of the heat dissipation plate 20 and cured to seal the wafer 10 and the heat dissipation plate 20.

Specifically, the sealing resin 30 may seal the wafer 10 and the heat dissipation plate 20 to protect the plurality of semiconductor devices 12 including silicon chips, gold wires, and a lead frame from heat, moisture, impact, and so on.

The sealing resin 30 may include epoxy molding compound (EMC). Here, the EMC may be a composite material composed of about ten raw materials including silica, an epoxy resin, a phenol resin, carbon black, and flame retardant.

In addition, the sealing resin 30 may be preferably formed of the EMC described above but it is not limited thereto and may include any sealing resin that may seal the wafer 10 and the heat dissipation plate 20.

By using the configuration described above, the wafer level chip scale package according to the embodiment of the present disclosure is manufactured by assembling an adhesive portion 40 and shoulder balls 50 as illustrated in FIG. 4, and may be separated according to positions of the plurality of semiconductor devices 12.

In the present specification, an example is used in which, when the plurality of semiconductor devices 12 are separated from each other by a laser cutter or a rotary blade cutter, a part of the silicon mold 11 is also divided.

The adhesive portion 40 may be provided as a die attach paste (DAP), which is an epoxy-based liquid adhesive, such that the heat dissipation plate 20 may be attached to the wafer 10.

In addition, the adhesive portion 40 may also be used to attach the shoulder balls 50, which is described below, to a printed circuit board (PCB) board such that a signal generated from the wafer 10 may be easily transmitted.

This adhesive portion 40 has a low thermal expansion coefficient, which may improve the reliability of a chip scale package, and has low viscosity to be injected even into minute areas, and thus, the heat dissipation plate 20 may be bonded more easily to the wafer 10. In addition, the adhesive portion 40 has a fast curing speed such that a curing process may be omitted after attaching the wafer 10 to the heat dissipation plate 20, and thus, a process time of a chip scale package may be reduced.

The shoulder balls 50 are formed at the bottom of the wafer 10 and may transmit signals generated from the plurality of semiconductor devices 12 to the outside, that is, to a PCB substrate connected thereto. When the shoulder balls 50 are formed at the bottom of the wafer 10, the shoulder balls 50 may be formed through a rearrangement layer/bump technology.

Here, the rearrangement layer/bump technology is the most widely used technology among wafer level package (WLP) technologies, and is implemented by extending the traditional wafer fabrication process to deposit a multilayer metal thin film wiring and systematically connect the plurality of semiconductor devices 12 on the wafer 10.

Through the additional process, outer bonding pads of each chip are rearranged in under bump metallurgy (UBM) pads in the form of a surface array uniformly distributed on a surface of the chip, and the shoulder balls 50 are sequentially placed on the UBM pads. The shoulder balls 50 may be formed in a ball shape as illustrated in FIG. 4, but this is an example, and any rearranged bump shape may be used and may be mounted on a board through a flip chip method to become an electrical connector in general.

In addition, the shoulder balls 50 may be bonded to points where the shoulder balls 50 have to be bonded through an encapsulated Cu process for forming contact points by electroplating copper (Cu) in the shape of a pillar. In this case, the adhesive portion 40 may perform a function of a shoulder mask, and an interface may also be adjusted by performing other surface treatments on a surface of a copper (Cu) post.

Accordingly, the wafer level chip scale package structure according to the embodiment of the present disclosure may effectively dissipate the heat generated during operations of the plurality of semiconductor devices 12 and may also prevent warpage of a large-area wafer.

Hereinafter, chip scale packages according to various shapes of the clip portion 22 will be described.

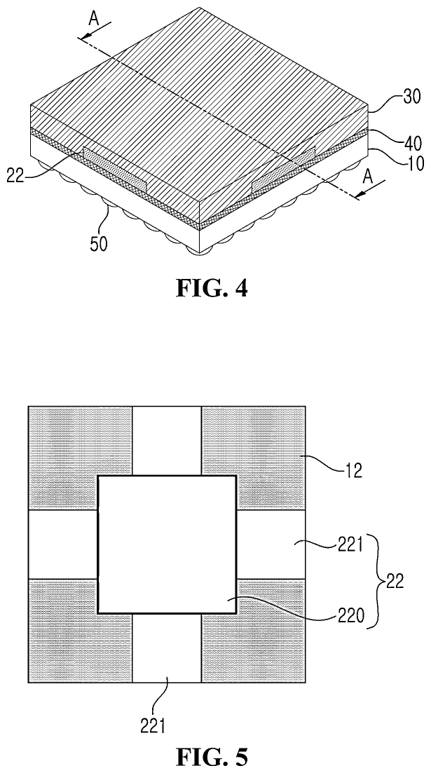

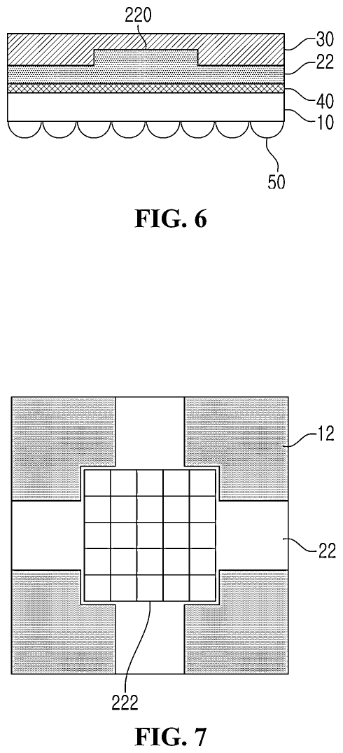

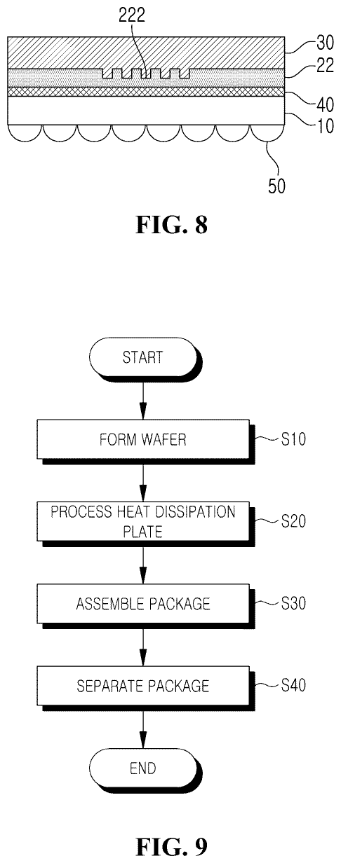

FIG. 5 is a plan view illustrating another shape of the clip illustrated in FIG. 3 and attached to a semiconductor device illustrated in FIG. 1, FIG. 6 is a cross-sectional view illustrating a state in which the clip illustrated in FIG. 5 is assembled to the chip scale package illustrated in FIG. 4 and cut along a cross-section line A-A, FIG. 7 is a plan view illustrating a state in which the clip illustrated in FIG. 3 is formed in another shape and attached to a semiconductor device illustrated in FIG. 1, and FIG. 8 is a cross-sectional view illustrating a state in which the clip illustrated in FIG. 7 is assembled to the chip scale package illustrated in FIG. 4 and cut along a cross-section line A-A.

Before describing the clip portion 22, it should be noted that a chip scale package described below may have the same configuration as the chip scale package described above, except for a shape of the clip portion 22.

Therefore, only a shape and effect of the clip portion 22 will be described.

Referring to FIG. 5, the clip portion 22 formed in a different shape may be formed in a cross shape according to a shape of the heat dissipation hole 21, and the clip portion 22 between the heat dissipation holes 21 may be thinner than the center of the clip portion 22 such that the center protrudes toward the sealing resin 30.

Hereinafter, for the sake of ease of description, a protruding portion will be referred to as a central portion 220, and a thin portion will be referred to as a wing portion 221.

In this case, the central portion 220 may be formed to protrude in a direction in which the sealing resin 30 is applied, and accordingly, the wing portion 221 may be formed to be thin such that protrusion of the central portion 220 increases.

In another example, in order for the central portion 220 to protrude, another component formed of the same material as a material of the clip portion 22 may also be attached to an upper surface of the central portion 220 without being processed.

That is, the central portion 220 and the wing portion 221 of the clip portion 22 may be formed to have a predetermined step difference, and accordingly, when a chip scale package is manufactured as illustrated in FIG. 6, the central portion 220 may be fitted into the center of the hardened sealing resin 30.

Referring to FIG. 7, the clip portion 22 formed in another shape may be formed in a cross shape according to the shape of the heat dissipation hole 21 described above, and the clip portion 22 of such a shape may include a groove 222 formed in a grid shape in the center.

The groove 222 may be formed according to a size of the central portion 220 of the clip portion 22 of another shape but is not limited thereto, and any grid shape having a width and area into which the sealing resin 30 may be injected and hardened as illustrated in FIG. 8 may be formed.

Accordingly, the wafer level chip scale package structure according to the embodiment of the present disclosure has an effect of improving reliability by increasing a coupling force between the clip portion 22 and the sealing resin 30 according to various shapes of the clip portion 22.

In addition, the shape of the clip portion 22 described above is an example, and various shapes that may increase the coupling force between the clip portion 22 and the sealing resin 30 may also be applied.

Hereinafter, a method of manufacturing a wafer level chip scale package, according to an embodiment of the present disclosure, will be specifically described.

FIG. 9 is a flowchart of a method of manufacturing a wafer level chip scale package, according to an embodiment of the present disclosure.

Referring to FIG. 9, the method of manufacturing a wafer level chip scale package may include step S10 of forming a wafer, step S20 of processing a heat dissipation plate, step S30 of assembling a package, and step S40 of separating a package.

First, step S10 may be a step of arranging the plurality of semiconductor devices 12 of the same size in the silicon mold 11 in rows and columns. In step S10, an ingot manufacturing process, an ingot cutting process, and a wafer surface polishing process are performed to manufacture a wafer.

In addition, in the wafer surface polishing process, an insertion groove into which the semiconductor device 12 is inserted may be processed in the silicon mold 11, but this is an example, and in addition to the insertion groove, a partition may be processed such that the semiconductor device 12 is safely placed at a certain interval.

step S20 may be a step of processing the heat dissipation plate 20 according to the number of semiconductor devices 12 arranged on the wafer 10.

Specifically, step S20 may be a step of forming the heat dissipation hole 21 according to an edge of the semiconductor device 12. In this case, in step S20, the heat dissipation hole 21 that is suitable for the semiconductor device 12 may be formed in the heat dissipation plate 20 through laser processing.

In addition, in step S20, after the heat dissipation hole 21 is formed, the clip portion 22 remaining in the heat dissipation plate 20 due to the formation of the heat dissipation hole 21 may be processed. In this case, the clip portion 22 is in contact with an upper surface of the semiconductor device 12 and is sealed by the sealing resin 30, and thus, the heat generated by the semiconductor device 12 may be dissipated to the outside.

For example, in step S20, the clip portion 22 may be processed such that the central portion 220 of the clip portion 22 protrudes in a direction in which the sealing resin 30 is applied, that is, on an upper side.

In another example, in step S20, the clip portion 22 may form the groove 222 having a grid shape in the central portion 220.

The shape of the clip portion 22 described above may allow the sealing resin 30 and the heat dissipation plate 20 to be more strongly bonded to each other in step S30.

Step S30 may be a step of assembling a package by bonding the wafer 10 to the heat dissipation plate 20 and then sealing the heat dissipation plate by placing the sealing resin 30 on an upper surface of the heat dissipation plate 20.

Specifically, in step S30, the wafer 10 may be first attached to the heat dissipation plate 20 by using the adhesive portion 30. In this case, a diameter of the silicon mold 11 of the wafer 10 and a diameter of the warpage prevention portion 23 of the heat dissipation plate 20 may be formed to be the same as each other such that a position of the semiconductor device 12 of the wafer 10 and a position of the heat dissipation hole 21 of the heat dissipation plate 20 are properly aligned.

thereafter, in step S30, the sealing resin 30 may be placed on an upper surface of the heat dissipation plate 20 to seal the wafer 10 and the heat dissipation plate 20, and after the sealing resin 30 is completely cured, the shoulder balls 50 may be connected to a lower surface of the wafer 10 to manufacture a plurality of chip scale packages.

The chip scale package described above may be separated according to a position of each of the plurality of semiconductor devices 12 through step S40.

In step S40, the chip scale package may be cut by a laser cutter or a rotary blade cutter, and a part of the silicon mold 11 may also be separated together to protect the semiconductor device 12 but is not limited thereto.

The separated chip scale package may be connected to a PCB substrate through the shoulder balls 50, and may also be stored to use other semiconductor devices 12.

Accordingly, the method of manufacturing a wafer level chip scale package, according to the embodiment of the present disclosure, has effects of being able to effectively dissipate the heat generated during an operation of the semiconductor device 12 and providing a chip scale package with improved reliability through a simple process of the clip 22.

Although embodiments of the present disclosure are described above with reference to the attached drawings, those skilled in the art to which the present disclosure belong will understand that the present disclosure may be implemented in other specific forms without changing the technical idea or essential features of the present disclosure. Therefore, the embodiments described above are examples in all aspects and are not restrictive.

1. A wafer level chip scale package structure comprising:
a wafer having arranged therein a plurality of semiconductor devices;
a heat dissipation plate attached to an upper end of the wafer based on positions of the plurality of semiconductor devices; and
a sealing resin disposed on an upper portion of the heat dissipation plate, wherein the sealing resin is configured to be cured and to seal the wafer and the heat dissipation plate,
wherein the wafer level chip scale package structure is configured to be separated into a plurality of chip scale packages, each of the plurality of chip scale package including the wafer including a semiconductor device, the heat dissipation plate, and a portion of the sealing resin bonded to each other according to the semiconductor device.

2. The wafer level chip scale package structure of claim 1, wherein the heat dissipation plate comprises:
a plurality of heat dissipation holes formed to partially expose areas of vertices of the plurality of semiconductor devices, wherein a number of the plurality of heat dissipation holes is equal to a number of the plurality of semiconductor devices;
a plurality of clips formed in a cross shape between the plurality of heat dissipation holes according to shapes of the plurality of semiconductor devices and dissipating heat between the plurality of semiconductor devices and the sealing resin; and
a warpage prevention portion attached to an upper surface of the wafer in which the plurality of semiconductor devices are not formed.

3. The wafer level chip scale package structure of claim 1, wherein the each of the plurality of chip scale package further comprises:
an adhesive portion configured to attach the wafer to the heat dissipation plate; and
a plurality of shoulder balls disposed at a bottom of the wafer and configured to transmit signals generated by the semiconductor device to an external device.

4. The wafer level chip scale package structure of claim 2, wherein
the plurality of clips are each formed in a cross shape according to the shapes of the plurality of heat dissipation holes, and
clip portions between the plurality of heat dissipation holes are thinner than centers of the plurality of clips and the centers protrude toward the sealing resin.

5. The wafer level chip scale package structure of claim 2, wherein
the plurality of clips respectively include grooves formed in a grid shape in centers of the plurality of clips, and
the sealing resin is injected into the grooves.

6. A method of manufacturing a wafer level chip scale package, the method comprising:
forming a wafer by arranging in a mold a plurality of semiconductor devices, each having the same size;
forming a plurality of heat dissipation holes in a heat dissipation plate corresponding to a number of the plurality of semiconductor devices;
manufacturing a plurality of chip scale packages by bonding the wafer to the heat dissipation plate, placing a sealing resin on an upper surface of the heat dissipation plate to which the wafer is bonded, and connecting a plurality of shoulder balls to the wafer; and
separating the plurality of chip scale packages from each other according to positions of the plurality of semiconductor devices.

7. The method of claim 6, wherein,
in the forming of the plurality of heat dissipation holes, the plurality of heat dissipation holes are formed to be aligned with edges of the plurality of semiconductor devices, and then a plurality of clips are processed such that the heat dissipation plate partially protrudes in a direction in which the sealing resin is applied.

8. The method of claim 6, wherein,
in the forming of the plurality of heat dissipation holes, the plurality of heat dissipation holes are formed to be aligned with edges of the plurality of semiconductor devices, a plurality of chips are processed, and grooves, each having a grid shape, are formed in centers of the plurality of clips of the heat dissipation plate, and
in the manufacturing of the plurality of chip scale packages, the sealing resin is injected into the grooves and cured.
